(19) United States
(12) Patent Application Publication
(10) Pub. No.: US 2026/0276558 A1
(43) Pub. Date: Sep. 17, 2026

(54) Defect Inspection System

(71) Applicant: Hitachi High-Tech Corporation, Minato-ku, Tokyo (JP)

(72) Inventors: Tomohiro MARUYAMA, Tokyo (JP); Masaya YAMAMOTO, Tokyo (JP); Masami MAKUUCHI, Tokyo (JP)

(21) Appl. No.: 19/163,926

(22) PCT Filed: Jun. 13, 2023
(86) PCT No.: PCT/JP2023/021943

§ 371 Date: Sep. 10, 2025

(51) Int. Cl. G01N 21/95

(52) U.S. Cl. CPC G01N 21/9501; G01N 2201/021; G01N 2201/06113; G01N 2201/103; G01N 2201/105; G01N 2201/121

(57) ABSTRACT

In order to accurately correct positional deviation due to vibration even in a state in which defect inspection is being performed under various inspection modes (inspection conditions), the present disclosure proposes a defect inspection system comprising (i) a lighting detection unit having a light source that irradiates a sample with light, and a detector that detects light from the sample, (ii) a stage mechanism for holding the sample that includes a rectilinear stage and a rotary stage, position sensors that measure the position of the rectilinear stage and the rotary stage, and an accelerometer for measuring the vibration of the rectilinear stage and the rotary stage, and (iii) a control unit for obtaining defect coordinates indicating the position of a defect on the basis of measurement values from the position sensors, wherein (iv) the control unit compares an output reference model of the accelerometer that has been calculated in advance in accordance with an inspection mode defining a sample inspection method, with a value actually measured by the accelerometer during the inspection of the sample in accordance with the inspection mode, to determine a mechanical positional deviation amount in the stage mechanism, and corrects the defect coordinates using the mechanical positional deviation amount (see FIG. 6).

### TECHNICAL FIELD

The present invention relates to a defect inspection system.

### BACKGROUND ART

In the semiconductor manufacturing process, defects in the sample (such as scratches and foreign matter) have a large impact on the yield, and it is important for yield management to feedback defect inspection information obtained from a defect inspection device to the semiconductor manufacturing process and manufacturing apparatus. Therefore, defect inspection devices that perform in-line inspection of samples such as wafers play a large role in the semiconductor manufacturing process.

Regarding defect inspection, for example, PTL 1 discloses a defect inspection device that combines a rotational movement θ, which is the main scanning, and a linear (translational) movement R, which is the sub-scanning, to scan an illumination spot (the illumination light irradiation position) in a spiral on the surface of a semiconductor wafer to detect defects. PTL 1 also discloses that the defect inspection device operates in a plurality of different inspection modes, including a defect inspection mode using Constant Angular Velocity (CAV) scanning, Constant Linear Velocity (CLV) scanning, and an acceleration/deceleration inspection in which inspection is performed even during rotational acceleration or deceleration of the sample stage. In each inspection mode, the irradiation speed and the associated irradiation amount per inspection point change in areas of different radial distances during the process of inspecting a circular sample such as a semiconductor wafer by rotating and scanning it from the inner circumference to the outer periphery, or from the outer periphery to the inner circumference.

### CITATION LIST

### Patent Literature

PTL 1: WO2021/014623A

### SUMMARY OF INVENTION

### Technical Problem

Defect inspection devices are constantly required to improve their inspection sensitivity and throughput. However, there is a trade-off between sensitivity and throughput. The acceleration/deceleration inspection disclosed in PTL 1 is a mode that shortens the total inspection time by utilizing a portion of the time during which no inspection was performed, during which the stage is accelerating or decelerating to a constant speed, as inspection time. This is therefore a very useful means for improving throughput.

On the other hand, the acceleration/deceleration inspection mode has difficulty in control. This is because, compared to when the stage is rotated at a constant speed and then the sample is inspected, in the inspection during acceleration or deceleration, the vibrations occurring throughout the illumination beam irradiating the sample, the stage, and the entire device become more complex. In particular, in defect inspection devices that use a plurality of inspection modes such as Constant Angular Velocity (CAV) scanning and Constant Linear Velocity (CLV) scanning as described in PTL 1, the tendency of vibration changes depending on the mode.

However, in technology such as that disclosed in PTL 1, it is desirable to take measures against the effects of vibrations caused by different inspection modes. Such vibrations affect the accuracy of the defect coordinates output by the defect inspection device. In particular, when the sample is a semiconductor wafer, the size of defects to be detected is becoming smaller as semiconductor patterns become finer. To check the defect image, the defect inspection device outputs the presence or absence of a defect and its coordinates, and the defect image is checked based on the coordinates using a review SEM. In this case, when there is a deviation in the defect coordinates output by the defect inspection device, it takes a long time to find the defect with a review SEM, and throughput cannot be improved. In particular, the smaller the defect size to be checked, the more difficult it becomes to identify the defect position during subsequent observation with the review SEM, even with a slight coordinate deviation. As such, coordinate deviations caused by various vibrations within the defect inspection device are becoming less acceptable in the semiconductor field. Therefore, means is needed that can correctly correct the output defect coordinates even when a plurality of inspection modes are used.

In consideration of this situation, the present disclosure proposes a technology that accurately corrects positional deviation caused by vibrations even when defect inspection is being performed in various inspection modes (inspection conditions).

### Solution to Problem

To solve the above problem, the present disclosure provides a defect inspection system for inspecting defects in a sample, including: (i) an illumination and detection unit having a light source that irradiates a sample with light, and a detector that detects light from the sample, (ii) a stage mechanism that holds the sample and has a linear stage and a rotation stage, a position sensor that measures positions of the linear stage and the rotation stage, and an accelerometer that measures vibrations of the linear stage and the rotation stage; and (iii) a control unit that determines defect coordinates indicating the position of a defect based on measurement values from the position sensor, in which (iv) the control unit compares an output reference model of the accelerometer calculated in advance according to an inspection mode that specifies a method for inspecting the sample with a value actually measured by the accelerometer during inspection of the sample according to the inspection mode to determine a mechanical positional deviation amount in the stage mechanism, and corrects the defect coordinates using the mechanical positional deviation amount.

Further features related to the present disclosure will become apparent from the descriptions in this specification and the accompanying drawings. Further, aspects of the present disclosure are achieved and implemented by the elements and combinations of various elements and aspects set forth in the following detailed description and the appended claims.

The descriptions in this specification are merely typical examples and are not intended to limit the claims or application of the present disclosure in any way.

### Advantageous Effects of Invention

According to the technology of the present disclosure, it is possible to accurately correct positional deviation caused by vibrations even when defect inspection is being performed in various inspection modes (inspection conditions).

### BRIEF DESCRIPTION OF DRAWINGS

FIG. 1 is a diagram showing an example of a basic configuration of a defect inspection device 100.

FIG. 2 is a diagram for explaining an incident direction of illumination light and a feed direction of a sample by the defect inspection device.

FIG. 3 is a schematic diagram showing the movement path of a sample 1 inside the defect inspection device 100.

FIG. 4 is a plan view of a sample, showing a schematic representation of the scanning trajectory of the sample by the defect inspection device 100.

FIG. 5 is a diagram showing an example of the hardware configuration of a defect detection processing system 40.

FIG. 6 is a schematic diagram for explaining optical vibration and mechanical vibration in the defect inspection device 100.

FIG. 7 is a flowchart for explaining processing performed by the defect detection processing system 40.

FIG. 8 is a diagram showing a defect coordinate deviation (example) on a wafer.

FIG. 9A is a diagram showing an illumination light spot S10 applied to the sample 1 and the trajectory example of a scanning line.

FIG. 9B is a diagram showing an example of the trajectory of an illumination light spot S20 on a light beam position sensor 50 (change in the beam spot on the light beam position sensor).

FIG. 10A is a diagram showing the position (example) of a defect when there is no mechanical vibration.

FIG. 10B is a diagram showing the position (example) of a defect when there is mechanical vibration.

FIG. 11A is a diagram showing the speed change of a linear stage during CAV scanning.

FIG. 11B is a diagram showing the output change of an acceleration sensor 70 (in one axial direction) during CAV scanning.

FIG. 11C is a diagram showing the output change of a displacement sensor 60 (in one axial direction) during CAV scanning.

### DESCRIPTION OF EMBODIMENTS

An embodiment of the present disclosure relates to a defect inspection system that inspects a defect in a sample such as a wafer. This embodiment discloses a technology for correcting the amount of deviation of defect coordinates in a defect inspection system by taking into account both mechanical vibrations caused by vibrations of a stage on which a sample is placed and optical vibrations caused by fluctuations of laser light in an illumination system, even in the different inspection modes (CAV, CLV, acceleration/deceleration inspection mode, etc.).

Hereinafter, an embodiment of the present disclosure will be described in detail with reference to the accompanying drawings. In the accompanying drawings, functionally identical elements may be denoted by the same numbers. The accompanying drawings show specific embodiments and implementation examples according to the principles of the present disclosure, but these are for the purpose of understanding the present disclosure and are not to be used in any way to interpret the present disclosure in a limiting manner.

Furthermore, in this embodiment, the description is provided in sufficient detail to enable a person skilled in the art to implement the present disclosure, but it should be understood that other implementations and forms are possible, and that changes to the configuration and structure and replacement of various elements are possible without departing from the scope and spirit of the technical ideas of the present disclosure. Therefore, the following description should not be interpreted as being limited to this.

### <Configuration Example of Defect Inspection Device>

Here, the basic configuration of the defect inspection device (defect inspection system) 100 will be described. To simplify the explanation, the configuration of the part excluding the mechanical and optical vibration correction function will be described first.

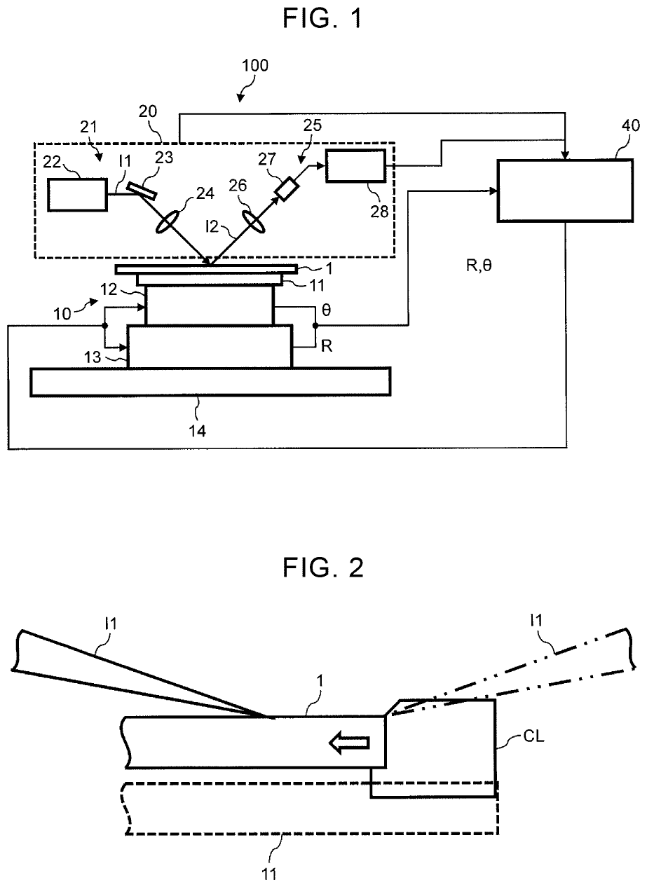

FIG. 1 is a diagram showing an example of the basic configuration of the defect inspection device 100. The defect inspection device 100 shown in FIG. 1 is a type of irradiating the sample 1, which moves in a straight line while rotating, with illumination light I1, and scanning the sample 1 in a spiral or concentric shape to inspect defects in the sample 1. The sample 1 can has, for example, a circular plate-shape such as a wafer (including a wafer at each step of semiconductor manufacturing process such as a bare wafer, a filmed wafer, and a patterned wafer). However, semiconductor device substrates other than wafers may also be used, and the sample 1 is not limited to wafers. Furthermore, defects detected by inspection include scratches and undulations of the sample 1, and foreign matter attached to the sample 1.

The defect inspection device 100 basically includes a stage device 10, an illumination and detection unit 20, an anti-vibration mount 14, and a defect detection processing system 40 which includes a data processing circuit (not shown) and a stage control circuit (not shown). These elements will be described in turn.

### (i) Stage Device

The stage device 10 is a rotary and linear stage equipped with the functions of rotary motion and linear (translational) motion. The stage device 10 includes a sample stage 11, a rotation stage 12, and a linear stage 13. The stage device 10, together with the illumination and detection unit 20, is installed on an anti-vibration mount 14 for reducing disturbance vibrations from other units outside and inside the apparatus.

The sample stage 11 is a stage that holds the sample 1 such as a wafer horizontally. The sample stage 11 can be of various types, such as one that holds the sample 1 by suctioning the backside of the sample 1 (disclosed, for example, in JP-A-1999-233597) or one that holds the sample 1 with the backside raised by gripping the edge of the sample. A sample stage that suctions the backside of the sample 1 is used, for example, when the defect inspection device 100 is used by a semiconductor device manufacturer. A sample stage that holds the sample 1 with the backside raised is used, for example, when the defect inspection device 100 is used by a wafer manufacturer that does not allow the backside of the sample 1 to come into contact with the sample stage. The sample stage that holds the sample 1 by raising the backside includes, for example, a type of holding the outer periphery of the sample 1 with a clamp CL (see FIG. 2) and a type of holding the sample 1 with a pressure member while raising the sample 1 with air pressure (disclosed, for example, in JP-T-2017-504199).

The rotation stage 12 is a stage that supports the sample stage 11. Further, the rotation stage 12 rotates around a vertical axis of rotation (not shown), rotating the sample 1 together with the sample stage 11. The rotation stage 12 is equipped with an optically readable rotary encoder (not shown). The rotary encoder detects the rotation angle (0 coordinate) of the rotation stage 12 and outputs the information to the defect detection processing system 40. However, the detector for detecting the 0 coordinate is not limited to a rotary encoder, and any sensor that can detect the rotation angle with high accuracy can be used instead of the rotary encoder.

The linear stage 13 is a stage that supports the rotation stage 12. The linear stage 13 moves along a rail (not shown) that extends in the radial direction (R-axis direction) of the rotation stage 12, and moves the sample 1 horizontally and linearly together with the rotation stage 12 and the sample stage 11. The linear stage 13 is equipped with an optically readable linear encoder (not shown). The linear encoder detects the position (R coordinate) of the linear stage 13 on the R axis and outputs the information to the defect detection processing system 40. However, the detector for detecting the R coordinate is not limited to a linear encoder, and any sensor that can accurately detect a position on a straight line can be used instead of the linear encoder.

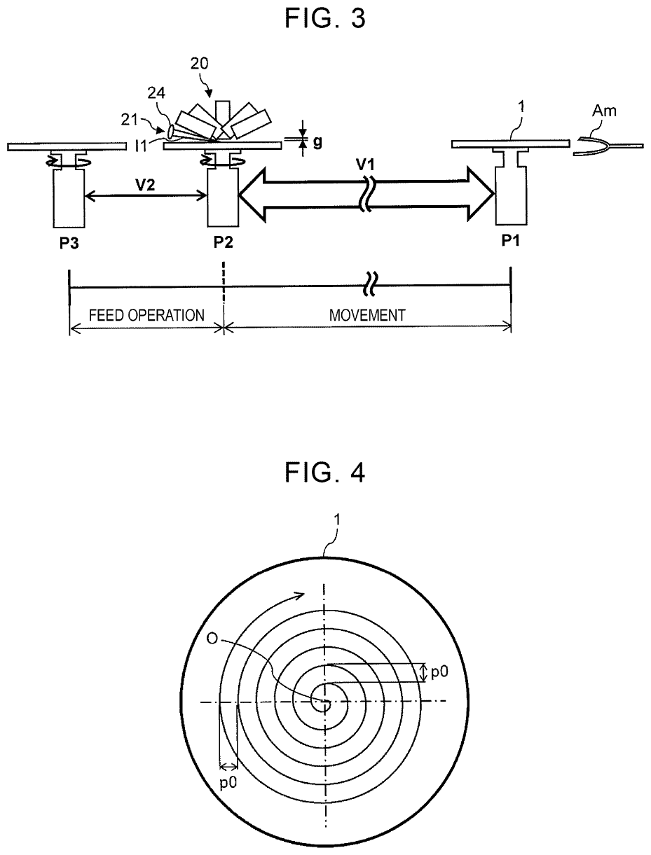

FIG. 3 is a schematic diagram showing the movement path of the sample 1 inside the defect inspection device 100. In this embodiment, as shown in FIG. 3, a sample transfer position P1 and a scan start position P2 are set on the R axis, which is the linear track of the linear stage 13. A stage control circuit (not shown) in the defect detection processing system 40 is configured to drive the linear stage 13 to move the rotation stage 12 along a straight line including the sample transfer position P1 and the scan start position P2. The scan start position P2 is a position where the sample 1 is irradiated with the illumination light I1 and scanning of the sample 1 is started. Specifically, the scan start position P2 is a position where a specific point on the sample 1 (in this embodiment, the center O (FIG. 4)) coincides with the illumination light spot (the focal position of the illumination light I1) of the illumination and detection unit 20. The other sample transfer position P1 is a position where the movement of the sample 1 to the scan start position P2 starts. The sample transfer position P1 also serves as a position where the sample 1 is attached or detached (loaded and unloaded) to or from the sample stage 11 by, for example, the transport arm Am (FIG. 3). This sample transfer position P1 is away from the illumination light spot. In this embodiment, the distance between the sample transfer position P1 and the scan start position P2 is approximately 150 mm to 500 mm. Note that a position P3 indicates the position when the periphery of the sample 1 is scanned (sample periphery scanning position).

### (ii) Illumination and Detection Unit

The illumination and detection unit 20 includes an illumination optical system 21 and a detection optical system 25. The illumination optical system 21 is an optical system that irradiates the sample 1 with illumination light I1, and includes an illumination light source (laser light source, etc.) 22 and a plurality of optical elements 23. The detection optical system 25 is an optical system that detects the inspection light 12 scattered or reflected by the sample 1, and includes a condensing optical element (condenser lens) 26, a photodetector 27, and a detection circuit 28. Since high inspection sensitivity is required, the illumination and detection unit 20 is in close proximity to the sample 1 (FIG. 3). When the sample stage 11 is directly below the illumination and detection unit 20, the gap G between the sample stage 11 and the illumination and detection unit 20 is about a few mm or less. The defect inspection device 100 of this embodiment is configured such that the distance between the illumination and detection unit 20 (the optical element at the lowest position) and the sample 1 is 0.5 mm to 5 mm or less in order to widely introduce the illumination light into the detector. Since it is difficult to transport the sample 1 using the transport arm Am and insert it into this gap G to place it on the sample stage 11, a sample transfer position P1 is provided as shown in FIG. 3.

In this embodiment, the illumination optical system 21 is installed on the opposite side of the sample transfer position P1 across the scan start position P2. Therefore, the illumination light I1 is applied obliquely onto the sample 1 from the opposite side of the sample transfer position P1 (see FIG. 3). A configuration for oblique irradiation is adopted to position the illumination optical system 21 to avoid the working space for loading and unloading the sample 1 and to reduce the distance between the sample transfer position P1 and the scan start position P2. The illumination light source 22 is equipped with a shutter (not shown) and is configured to irradiate the illumination light I1 onto the sample 1 or block the illumination light I1 by opening and closing the shutter.

FIG. 4 is a plan view of a sample, which shows a schematic representation of the scanning trajectory of the sample by the defect inspection device 100. When the shutter of the illumination light source 22 opens, the illumination light I1 emitted from the illumination light source 22 is applied onto the sample 1 via a plurality of optical elements 23. By moving the sample 1 held by the stage device 10 in a straight line (translation) while rotating it, the illumination light I1 is applied along a spiral trajectory (scanning pitch: p0) from the center O of the sample 1 to its outer edge, as shown in FIG. 4, and the entire surface of the sample 1 is scanned. The inspection light 12 scattered or reflected by the sample 1 is detected via a condensing optical element (condenser lens) 26, a photodetector (e.g., a photoelectric sensor) 27, and a detection circuit 28. The detection circuit 28 outputs the detection result to a data processing circuit (not shown) in the defect detection processing system 40.

The defect detection processing system 40 is programmed to drive the linear stage 13 in a direction approaching the illumination optical system 21 from the scan start position P2 during defect inspection. In other words, in this embodiment, the illumination optical system 21 is located on the opposite side of the sample transfer position P1. Therefore, during sample scanning, the movement of the linear stage 13 is controlled in a direction away from the sample transfer position P1, starting from the scan start position P2. Thus, even when the sample stage 11 is configured to hold the sample 1 with a plurality of clamps CL as shown in FIG. 2, for example, it is possible to scan the sample from the center O of the sample 1 to the outer edge while avoiding interference between the illumination light I1 and the clamps.

In other words, since the incidence angle (angle to vertical) of the illumination light I1 to the sample 1 is large, if the illumination light I1 is irradiated from the sample transfer position P1 side as shown by the two-dot chain line in FIG. 2, the clamp CL blocks the light at the end of the scan, and the outer periphery of the sample 1 cannot be sufficiently inspected. Furthermore, even if the arrangement of the illumination optical system 21 and the feed direction of the linear stage 13 during scanning are the same as in the present embodiment, when scanning is started from the outer periphery of the sample 1 (scan start position P2 is set at the outer edge of the sample 1), a similar problem will occur at the beginning of the scan. In contrast, this embodiment is configured such that, even when using a sample stage 11 equipped with a clamp CL, for example, interference between the illumination light I1 and the clamp CL can be avoided from the start to the end of scanning, allowing full-surface inspection of the sample 1.

In addition, while FIG. 3 shows a case where the laser light is irradiated obliquely, other light sources such as a broadband light source can be adopted as the illumination light source 22, and the arrangement of the light source and the stage and the irradiation direction from the light source to the sample may differ depending on the type of light source.

(iii) Defect Detection Processing System

The defect detection processing system 40 is equipped with a data processing circuit (not shown) inside. The data processing circuit generates scan information (inspection results) from the detection results by the illumination and detection unit 20 and the Rθ coordinates output by the stage device 10. The scan information generated by the data processing circuit includes the positions of defects such as foreign matters and scratches, and the size and shape of the defects based on the amount of detection signals.

The defect detection processing system 40 further includes a stage control circuit (not shown). The stage control circuit is a circuit that controls the operation of the stage device 10. The stage control circuit can be configured with, for example, a motor driver that drives the drive device (motor) of the rotation stage 12 and a motor driver that drives the drive device (motor) of the linear stage 13. In the defect detection processing system 40, the stage control circuit drives the drive device based on command values for the operation of the stage device 10. This causes the rotation stage 12 and the linear stage 13 to operate.

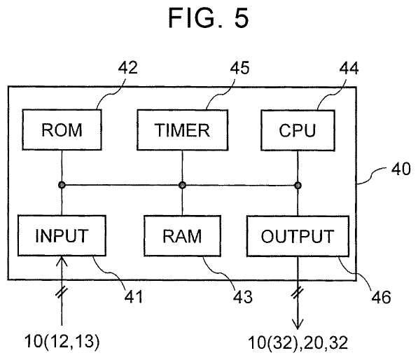

FIG. 5 is a diagram showing an example of the hardware configuration of the defect detection processing system 40. The defect detection processing system 40 is a computer that controls the operation of the illumination and detection unit 20, the rotation stage 12, and the linear stage 13 (stage device 10), etc. The defect detection processing system 40 includes, for example, an input interface 41, a ROM (e.g., EPROM) 42, a RAM 43, a CPU 44, a timer 45, an output interface 46, or the like.

The input interface 41 transfers to the CPU 44 signals (R and 0 coordinates of the sample stage 11) from the encoders of the rotation stage 12 and the linear stage 13, and inspection conditions input from an input device (not shown) such as a keyboard in response to an operator's operation. The inspection conditions include, for example, the type, size, shape, etc. of the sample 1 and information on the inspection mode. The ROM 42 stores arithmetic expressions, programs (described later), and data required for defect inspection. The RAM 43 stores numerical values during calculation and information such as inspection conditions input from the input device. The output interface 46 outputs command signals to the stage device 10 and the illumination and detection unit 20 in response to commands from the CPU 44. The defect detection processing system 40 also outputs coordinate detection signals (calculated R, θ coordinates of the sample stage 11) of the rotation stage 12 and the linear stage 13 to a data processing circuit (not shown) via the output interface 46.

The CPU 44 executes predetermined processes based on information input via the input interface 41 in accordance with the program loaded from the ROM 42. The stage device 10 and the illumination and detection unit 20 are also controlled by command values output from the CPU 44 based on the inspection conditions and the Rθ coordinates of the sample stage 11 to be measured, thereby scanning the sample 1.

### <Inspection Modes>

The defect inspection device 100 can operate in a plurality of inspection modes, such as Constant Angular Velocity (CAV) inspection, Constant Linear Velocity (CLV) inspection, and acceleration/deceleration inspection. CAV inspection is an inspection mode in which the rotation speed (angular velocity) of the rotation stage 12 during scanning is constant. CLV inspection is an inspection mode in which the linear velocity (scanning speed) is constant.

Acceleration/deceleration inspection is an inspection mode in which inspection is performed even during acceleration and deceleration. “During acceleration” means that inspection is not started after a predetermined stage rotation speed is reached, but means that inspection is started during the acceleration process until the predetermined stage rotation speed is reached. While the inspection is normally completed at a predetermined stage rotation speed and then the stage rotation is decelerated and stopped, “during deceleration” means that some inspection continues in the process of decelerating the rotation speed and is completed during the deceleration.

Here, the acceleration/deceleration inspection mode will be explained in detail. With a stage device 10 that has large inertia, it takes longer to increase the rotation speed of a stationary stage to the specified rotation speed (or to stop the sample stage rotating at the specified rotation speed) than to move in a straight line between the sample transfer position P1 and the scan start position P2. Thus, at the time when the sample stage 11 moves in a straight line from the sample transfer position P1 and arrives at the scan start position P2, the stage rotation speed has not reached the specified rotation speed. When the specified rotation speed is increased in response to a user request, the time required for rotational acceleration and deceleration will be extended. On the other hand, when the movement distance is shortened, the movement time will be shortened. In this case, the time difference between the time required for rotational acceleration and deceleration and the time required for stage movement becomes increasingly wider. If scanning is started with the stage rotating at the specified rotation speed as usual, there is a waiting time until the specified rotation speed is reached at the scan start position P2. When returning the sample stage 11 to the sample transfer position P1 after scanning, there may also be a time to wait for the sample stage 11 to stop rotating at the sample transfer position P1. If the specified rotation speed increases and the movement distance is shortened, the overall inspection processing time is expected to be shortened by shortening the scanning time and movement time, but on the other hand, the proportion of waiting time in the inspection processing time increases due to the increase in the time difference between the time required for rotation acceleration and the time required for movement.

Therefore, it is assumed that when the sample reaches the scanning position, scanning will start without waiting for the specified rotation speed to be reached. In other words, this is an inspection method that reduces the waiting time associated with acceleration and deceleration of stage rotation, especially acceleration, when moving the stage between the sample transfer position P1 and the scan start position P2 by reducing the distance between the sample (such as a wafer) and the optical system (illumination and detection unit) to achieve high sensitivity. In this inspection method, the net irradiation time can be maximized within a specified sequence by devising a way to control the linear velocity and angular velocity of the stage (described later).

The defect inspection device 100 can use different inspection modes, such as CAV inspection, CLV inspection, or acceleration/deceleration inspection, depending on the user's application and needs. On the other hand, because the defect inspection device 100 has different inspection modes, control of the illumination and detection unit 20 and the stage device 10 is required to correspond to each inspection mode, making the control method complicated.

The need for highly accurate control for each inspection mode is related to the industry situation of semiconductor devices becoming smaller and more complex. As semiconductor devices become smaller, the size of defects to be detected becomes smaller, and higher accuracy is required for their coordinates. Even in the defect inspection device 100 of this embodiment, positional deviation occurs when calculating defect coordinates. For example, positional deviation can be caused by optical vibration and mechanical vibration. Such positional deviation due to vibration was considered to be tolerable and minute in the past. However, as semiconductor devices themselves become smaller and the size of defects to be detected becomes smaller, the impact that such positional deviation due to vibration has on coordinate accuracy is becoming relatively greater. Therefore, even a minute positional deviation is no longer acceptable for the defect coordinate accuracy required by users.

### <Correction of Positional Deviation Due to Optical and Mechanical Vibrations>

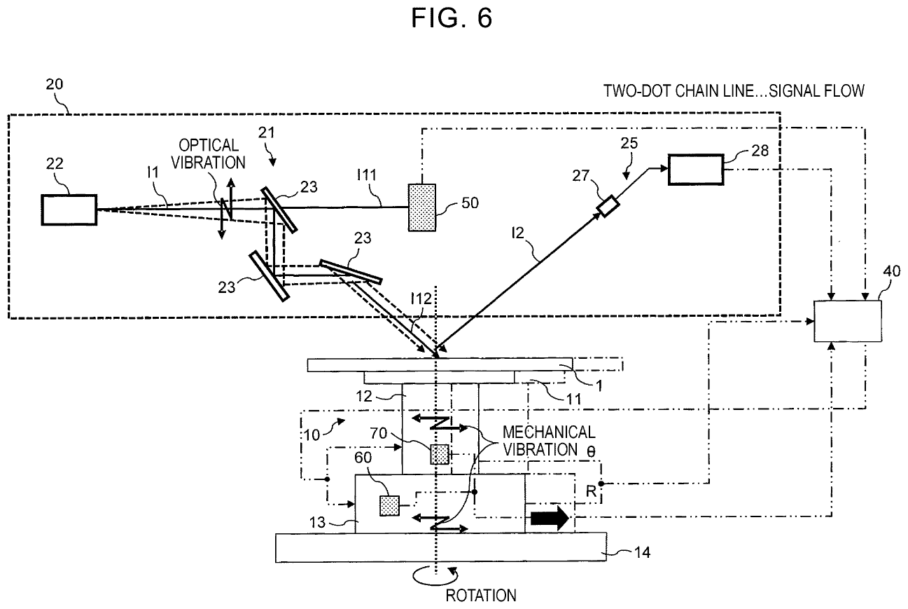

FIG. 6 is a schematic diagram for explaining optical vibration and mechanical vibration in the defect inspection device 100. As shown in FIG. 6, optical vibrations are caused by fluctuations in the illumination light I1 of the illumination optical system 21. The fluctuations in the illumination light I1 are caused by vibrations of the optical element 23 (mechanical vibrations of the stage device 10 are also a factor), vibrations of the air, and/or the external environment (temperature and humidity), etc. In particular, since the movement of the crystal inside the illumination light source (laser light source) 22 varies depending on the temperature, it is almost impossible to irradiate the illumination light I1 (laser light) at a single point (the irradiation position is not fixed at a single point). On the other hand, mechanical vibration is caused by the shaking of the rotation stage 12 and the linear (translation) stage 13 of the stage device 10.

In the defect inspection device 100, the detection optical system 25 detects the inspection light 12 scattered or reflected by the sample 1. The defect detection processing system 40 then calculates the defect coordinates based on the detection signal and the Rθ coordinates output from the stage device 10. At this time, correction is required to take into account the amount of deviation in coordinate information caused by optical vibration and mechanical vibration relative to the coordinates where the defect actually exists. In the related art, it is attempted to remove the effects of vibration using only the anti-vibration mount 14, but in this embodiment, the positional deviation amount caused by vibration (fine vibration) that is not be completely removed by the anti-vibration mount 14 is measured, and this positional deviation amount is reflected in the measured defect coordinates based on signal processing.

### (i) Measurement of Positional Deviation Amount Due to Optical Vibration on Illumination Optical System 21 Side

As shown in FIG. 6, the light beam position sensor 50 is installed on the illumination optical path from the illumination light source 22 to the sample 1 (on an extension of a part of the illumination optical path). It is preferable that the light beam position sensor 50 is installed downstream of the illumination optical path as much as possible. This is because the positional deviation caused by the vibration of the optical element 23 and the like downstream of the light beam position sensor cannot be accurately obtained. In addition, the light applied to the light beam position sensor 50 needs to be adjusted such that it is at the center of the light beam position sensor 50. For example, a reflective or transmissive optical element is placed on the irradiation optical path, and the optical path is adjusted such that the inspection light is near the center of the light beam position sensor 50 by the optical element. As a result, even during actual inspection, the beam is to enter the center of the light beam position sensor 50, but the beam is inevitably subject to shaking as it travels along the optical path. Therefore, the illumination light I11 entering the light beam position sensor 50 during actual inspection is slightly shifted from the center point. The light beam position sensor 50 detects the actual incident position. The difference between the actual incident position and the center point as the reference position can be used as the “positional deviation amount” output by the light beam position sensor 50. Further, a beam splitter may extract a portion of the light and input it to the light beam position sensor 50. With respect to the light beam position sensor 50, at least two sensors capable of measuring the deviation amount of both the angle and position of the illumination light I1, or capable of measuring positional deviation need to be installed on the optical path. This allows the position of the laser beam to be measured at all times. When two sensors are installed, the angle of the laser beam can be calculated from the position of the laser beam detected by each sensor.

### (ii) Measurement of Deviation Amount Due to Mechanical Vibration on Stage Device 10 Side

As shown in FIG. 6, the displacement sensor 60 is installed on the stage device 10, for example, the linear stage 13, on the anti-vibration mount 14. The acceleration sensor 70 is installed on the rotation stage 12 and measures the positional deviation in the R-axis and 0-axis directions. The anti-vibration mount 14 structurally reduces disturbance vibrations from other units outside and inside the device (it directly attenuates vibrations as a physical quantity (not by data processing)).

The displacement sensor 60 detects low-frequency external vibrations that cannot be removed by the anti-vibration mount 14. External vibrations include vibrations from the floor of a factory in which the defect inspection device 100 is installed, vibrations caused by the influence of vibrations from nearby device, and vibrations caused by fans within the device. On the other hand, the acceleration sensor 70 detects high-frequency vibrations such as vibrations caused by the rotational operation of the rotation stage 12, vibrations caused by accelerating or decelerating rotation, and vibrations caused by imbalance of a rotating body. In general, the displacement sensor 60 is highly sensitive to the low-frequency range, while the acceleration sensor 70 is highly sensitive to vibration measurements in the high-frequency range. The sum of the displacement amounts due to low-frequency and high-frequency vibrations output by these sensors can be taken as the “positional deviation amount” due to mechanical vibration.

In this way, optical vibrations caused by fluctuations in the illumination light I1 are detected by the light beam position sensor 50, and mechanical vibrations caused by shaking on the stage device 10 side are detected by the displacement sensor 60 and the acceleration sensor 70.

### <Processing Contents in Defect Detection Processing System 40>

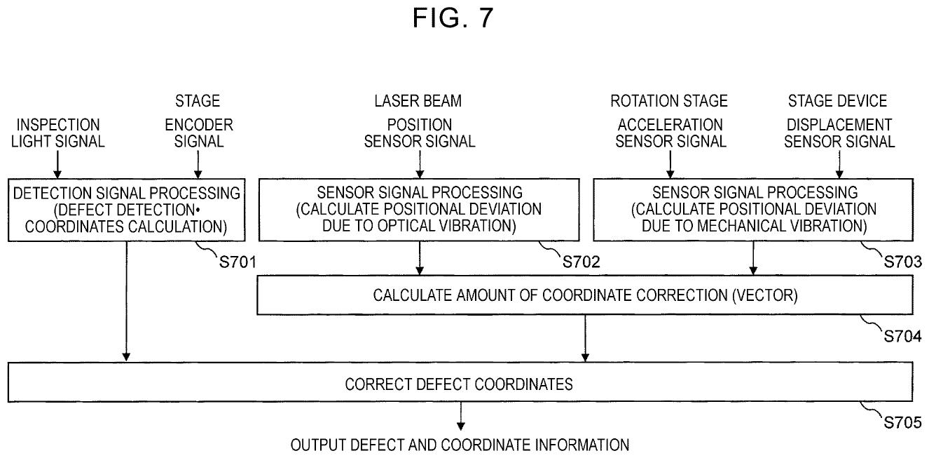

FIG. 7 is a flowchart for explaining the processing executed by the defect detection processing system 40.

### (i) S701

The defect detection processing system 40 detects defects from the inspection light I2 signal detected via the photodetector (e.g., photoelectric sensor) 27 and the detection circuit 28, and the stage encoder signal detected by the rotation stage encoder (not shown) and the translation stage encoder (not shown), and calculates the coordinates. The calculated coordinates include components of positional deviation due to the optical vibration and mechanical vibration described above.

### (ii) S702

The defect detection processing system 40 calculates the positional deviation amount of the illumination light 112 applied onto the sample 1 from the positional deviation amount of the illumination light I11 detected by the light beam position sensor 50.

Due to the relationship between the arrangements of the optical element and the light beam position sensor 50 in the illumination and detection unit 20, the distance from the illumination light source 22 to the light beam position sensor 50 may differ from the distance from the illumination light source 22 to the sample 1 (optical path distance). Therefore, the positional deviation amount of the illumination light I11 detected by the light beam position sensor 50 differs from the positional deviation amount of the illumination light 112 on the sample 1. Therefore, in this embodiment, the relative relationship between the positional deviation amount of the light beam position sensor 50 and the positional deviation amount on the sample 1 is obtained by measurement in advance, and the relative relationship is stored in a storage device (not shown) in the defect detection processing system 40 (for example, as a table). The defect detection processing system 40 may then acquire from the storage device the positional deviation amount of the illumination light 112 corresponding to the positional deviation amount of the illumination light I11 detected by the light beam position sensor 50. A detailed example of the calculation of the optical positional deviation amount will be described later.

(iii) S703

In parallel with S702, the defect detection processing system 40 calculates the positional deviation amount due to mechanical vibration by adding (vector sum) the displacement amount due to low-frequency vibration detected by the displacement sensor 60 installed on the stage device 10 on the anti-vibration mount 14 and the displacement amount due to high-frequency vibration detected by the acceleration sensor 70 of the rotation stage 12. A detailed example of the calculation of the amount of mechanical positional deviation will be described later.

### (iv) S704

The defect detection processing system 40 calculates the amount of coordinate correction, by vector summing the positional deviation amount due to optical vibration calculated in S702 and the positional deviation amount due to mechanical vibration calculated in S703.

### (v) S705

The defect detection processing system 40 reflects the amount of coordinate correction calculated in S704 to the coordinates calculated in S701, and outputs the presence or absence of a defect in the sample 1 and the coordinate value (correction value) of the defect.

### <Specific Details of Defect Coordinate Correction>

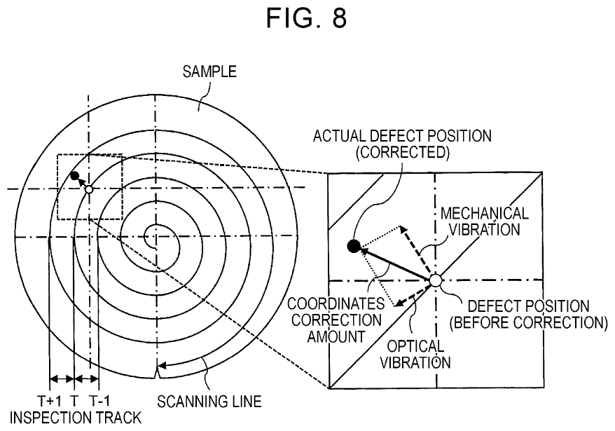

Next, how optical and mechanical vibrations affect defect coordinates and how they are corrected will be described in detail. FIG. 8 is a diagram showing a defect coordinate deviation (example) on a wafer.

### (i) Effects of Optical and Mechanical Vibrations

As shown in FIG. 6, illumination light 112 is applied to the sample 1 on the sample stage 11 on the rotation stage 12 via a plurality of optical elements 23. For example, first, the center position O of the sample 1 is irradiated. Then, in accordance with the operations of the rotation stage 12 and the linear stage 13, light is applied in a spiral pattern from the center to the outer periphery as shown in FIG. 8. Note that this trajectory may be a spiral trajectory that irradiates sequentially from the outer periphery toward the center. At this time, the light applied to the sample 1 vibrates due to the vibration of the optical element 23 on the optical path, changes in temperature and humidity around the illumination optical system 21 in the device, and the like. This causes the illumination position to shift relative to the scanning trajectory along which the illumination light is to be applied. This affects the defect coordinates to be output, reducing the accuracy of the defect coordinates.

As described above, mechanical vibrations are generated by the shaking of the rotation stage 12 and linear (translational) stage 13 of the stage device 10. Vibrations are generated simply by moving the linear stage 13 while rotating the rotation stage 12 at a high speed. In addition, vibrations generated inside and outside the defect inspection device 100 can be transmitted to the rotation stage 12, causing it to vibrate. These mechanical vibrations may cause the positions of the center of the sample 1 (reference value) and the center of the sample stage 11 to shift, resulting in a shift in the position of the scanning line as shown in FIG. 8.

In the defect inspection device 100 having a plurality of different inspection modes, there are factors that further complicate the correction of the amount of the positional deviation due to this vibration. For example, when the inspection mode (CAV inspection mode, CLV inspection mode, acceleration/deceleration inspection mode, etc.) differs, the rotation speed of the rotation stage 12 and the movement feed pitch of the linear stage also differ. Furthermore, there are inspection modes in which the rotation speed and feed pitch change during one inspection. Therefore, the vibration method and the magnitude and change of the positional deviation caused by it differ completely depending on the inspection mode.

### (ii) Introduction of Reference Model

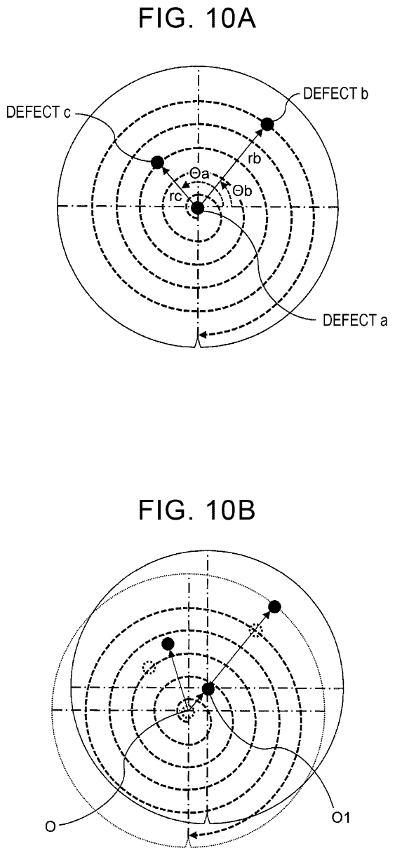

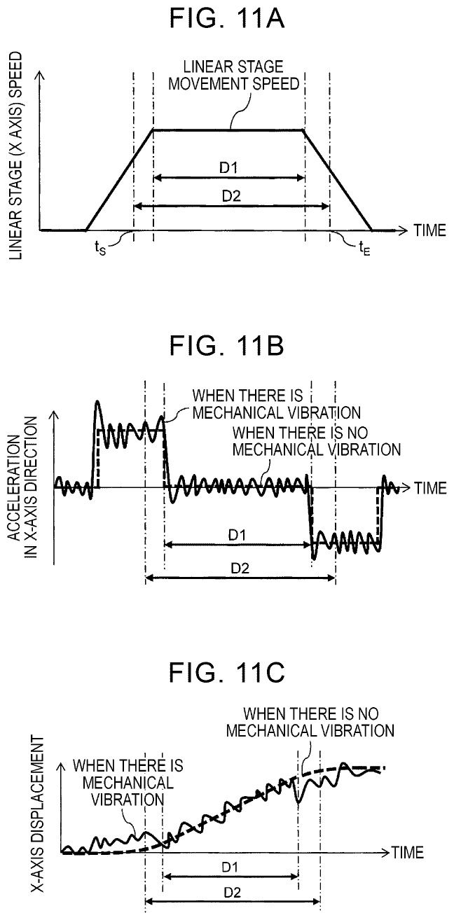

In order to be able to correctly calculate the positional deviation amount even when there is a difference in the positional deviation amount for each inspection mode, in this embodiment, a reference model for each sensor output is provided in advance for each inspection mode. For example, FIGS. 11B and 11C are diagrams showing a comparison between the reference model (shown by dotted lines in the figures) and the outputs of the displacement sensor 60 and the acceleration sensor 70 (shown by solid lines in the figures) in the acceleration/deceleration inspection mode, which is one of the inspection modes (inspection conditions). The reference model for displacement and acceleration is a model that represents the ideal form of what the displacement and acceleration of the rotation stage 12 are to be from the start to the end of the inspection. In contrast, in FIG. 11B and FIG. 11C, the accelerations (actual measurements) actually detected by the displacement sensor 60 and acceleration sensor 70 attached to the rotation stage 12 are plotted. The actually measured acceleration includes the effect of mechanical vibrations caused by the actual displacement amount of the anti-vibration mount 14 and the acceleration of the rotation stage 12. Therefore, a difference occurs between the detection values of the displacement sensor 60 and the acceleration sensor 70 for the displacement model and the acceleration model. In the acceleration/deceleration inspection mode, acceleration occurs at the beginning of one inspection, constant speed rotation occurs in the middle, and deceleration occurs near the end of the inspection (see FIG. 11A). Therefore, the reference values of the displacement model and the acceleration model are also different at the beginning, middle, and near the end of one inspection. Here, for example, it is assumed that defects a, b, and c are located at different radial distances from the center to the outer periphery as shown in FIG. 10A. In the case of a trajectory that scans in a spiral shape from the center of the sample to the outer periphery, the defect a near the center is inspected while the rotation stage is accelerating, the defect b is inspected while it is rotating at a constant speed, and the defect c is inspected while it is decelerating. The difference between the displacement and acceleration output by the displacement and acceleration sensor when each defect is detected and the displacement and acceleration model is the positional deviation amount that affects the defect coordinates.

(iii) Calculation of Positional Deviation Amount Due to Optical Vibration and Positional Deviation Amount Due to Mechanical Vibration

Next, the calculation of the positional deviation amount due to optical vibration calculated from the output of the light beam position sensor 50 and the positional deviation amount due to mechanical vibration calculated from the output of the acceleration sensor 70 and the displacement sensor 60 will be described in detail. When the positional deviation amount due to optical vibration (assumed to be a) and the positional deviation amount due to mechanical vibration (assumed to be β) are taken into account, the orthogonal coordinate system (X, Y) with the positional deviation amount corrected is expressed by the following Equation 1.

$$X = {α}_{X} + {β}_{X} + R \times cos θ \qquad ( Equation 1 )$$

$$Y = {α}_{Y} + {β}_{Y} + R \times sin θ$$

Here, α_{X} represents the X-direction component of the positional deviation amount due to optical vibration, and ay represents the Y-direction component of the positional deviation amount due to optical vibration. Furthermore, β_{X} represents the X-direction component of the amount of the positional deviation due to mechanical vibration, and β_{Y} represents the Y-direction component of the positional deviation amount due to mechanical vibration.

More accurate coordinates are obtained by measuring the positional deviation amount (α, β), calculating the amount of correction, and correcting the coordinate information of the inspection results in the related art. In this way, the defect detection processing system 40 calculates the coordinate correction amount (vector amount) and corrects the defect coordinates using this.

### (iv) Specific Example of Correction of Positional Deviation Amount due to Optical Vibration

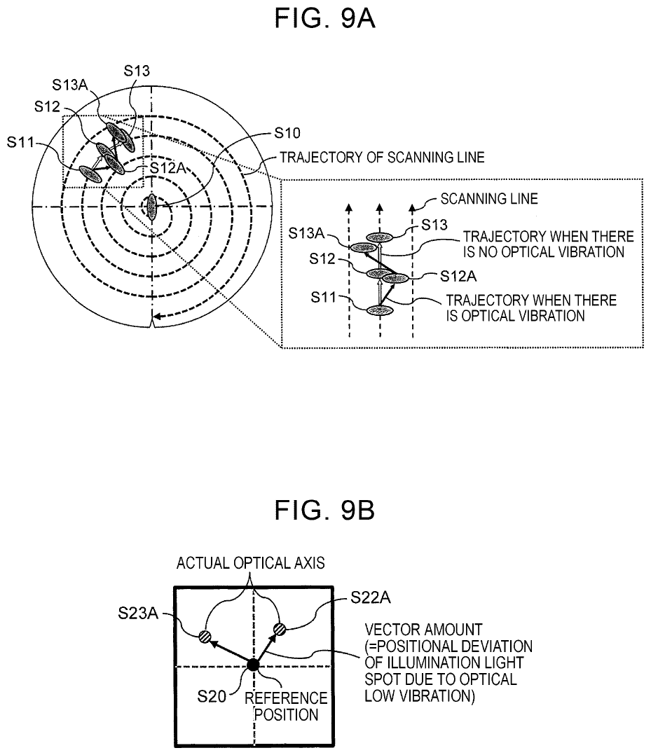

FIGS. 9A and 9B are diagrams for explaining a specific example of correction of the amount of deviation of defect coordinates due to optical vibration. FIG. 9A is a diagram showing an illumination light spot S10 applied to the sample 1 and the trajectory (example) of a scanning line. FIG. 9B is a diagram showing the trajectory (example) of the illumination light spot S20 on the light beam position sensor 50.

In FIG. 9A, S11, S12, and S13 show virtual illumination light spots when ideal scanning is performed when there is no influence of optical vibrations, and the rotation stage 12 and the linear stage 13 are not influenced by mechanical vibrations and are ideally controlled (in reality, optical vibrations and mechanical vibrations always occur during the process of irradiating the sample with illumination light).

When the rotation stage 12 and the linear stage 13 are operated, the illumination light spot S10 (scanning start point (inner circumference of the sample)) performs scanning in a spiral trajectory along the scanning line as shown by S11, S12, and S13 in an ideal state without vibration. Further, as shown in FIG. 9B, in a state without any vibration, the illumination light spot S20 applied onto the sensor surface of the light beam position sensor 50 is at the reference position.

On the other hand, when there is optical vibration, for example, the illumination light spot S11 vibrates, so the illumination light spot S12 and the illumination spot S13 are scanned at positions shifted from the scanning line as S12A and S13A. In this case, the illumination light spot S20 on the light beam position sensor 50 shown in FIG. 9B also shifts from the reference position as shown by S22A and S23A.

As described above, the illumination light spots S20, S22A, and S23A of the light beam position sensor 50 are correlated with the positions of the illumination light spots S10, S11, S12, and S13 applied onto the sample 1. This correlation is determined in advance by simulation, actual measurement, or the like. The difference between the beam position detected by the light beam position sensor 50 and a reference is determined as the amount of deviation in the light beam position sensor. Then, from this amount of deviation and the correlation determined in advance, the positional deviation amount of the illumination light spot applied to the sample 1 is calculated.

Finally, this is linked to the coordinate information obtained from the encoder signals of the rotation stage 12 and the linear stage 13. The defect detection processing system 40 performs this series of processing and reflects the amount of deviation due to optical vibration in the defect coordinates. This is coordinate correction for the amount of deviation due to optical vibration.

### (v) Specific Example of Correction of Positional Deviation due to Mechanical Vibration

FIGS. 10A and 10B are diagrams for explaining a specific example of correction of the amount of deviation of defect coordinates due to mechanical vibration. FIG. 10A is a diagram showing the position (example) of a defect when there is no mechanical vibration. FIG. 10B is a diagram showing the position (example) of a defect when there is mechanical vibration.

The defect coordinates are calculated based on the rotation angle (θ coordinate) and the position on the R axis (R coordinate) obtained from various encoders. In the case of FIG. 10A, the coordinates of defects a, b, and c without mechanical vibration are shown. On the other hand, in an actual inspection, when the inspection starts, mechanical vibration occurs due to the rotation or linear stage. As a result, the center position of the sample held on the sample stage 11 is shifted (O→O1). With respect to the original defect coordinates on the sample 1, due to the influence of mechanical vibration, the rotation angle and the position on the R axis are shifted from the center position of the sample 1 (O: the center position of the illumination light spot when there is no mechanical vibration) (O1: the center position of the illumination light spot when there is mechanical vibration). As a result, the defect coordinates calculated based on the rotation angle (θ coordinate) and the position on the R axis (R coordinate) obtained from various encoders are shifted from the original coordinates. The defect detection processing system 40 uses the difference (deviation amount) between the reference model and the actual output of the displacement sensor 60 and the acceleration sensor 70 to correct the deviation amount.

The correction of the deviation amount based on the reference model will be described. FIG. 11A shows the speed change of the linear stage during CAV scanning. FIG. 11B shows the output change of the acceleration sensor 70 (in one axial direction) during CAV scanning. FIG. 11C shows the output change of the displacement sensor 60 (in one axial direction) during CAV scanning. In FIGS. 11B and 11C, the dotted lines show the reference model, which is an ideal output when there is no mechanical vibration. In FIGS. 11A to 11C, D1 indicates an inspection mode in which inspection is performed while the rotation stage 12 is rotating at a constant speed (i.e., no inspection is performed during acceleration or deceleration). D2 indicates an inspection mode in which inspection is performed even while the rotation stage 12 is accelerating or decelerating. In FIG. 11A, ts indicates the measurement start timing (time). The time until ts indicates the time period during which the sample 1 is transported from the sample transfer position P1 to the scan start position P2. In addition, the indicates the measurement end timing (time). The time from the indicates the time period during which the sample 1 is transported from the scan end position to the sample transfer position P1. Furthermore, FIG. 11B shows that, as shown by D2, acceleration increases during acceleration/deceleration and acceleration becomes zero during uniform motion.

On the other hand, when mechanical vibrations are present, displacements occur steadily due to external vibrations or vibrations of the rotation stage 12. In particular, during acceleration and deceleration, the displacement increases due to vibrations caused by the inertial force of the stage. Therefore, during acceleration and deceleration inspection, the defect coordinate deviation increases between the inside and outside of the sample 1. In the same way, in the rotation stage 12, vibrations occur due to imbalance in the sample stage 11 even at the same rotation speed. The magnitude of vibration varies depending on the rotational speed of the sample stage 11. Therefore, the displacement amount due to vibration also varies depending on the inspection mode and the sample surface. Low-frequency vibrations that cannot be completely removed by the anti-vibration mount 14 are measured by the displacement sensor 60. The low-frequency vibration values are then linked to the rotation angles (θ coordinate) and positions on the R axis (R coordinate) of the rotation stage 12 and linear stage 13. The measurement data from the accelerometer is also linked to the rotation angle (θ coordinate) and position on the R axis (R coordinate). Ultimately, regardless of the inspection mode, the amount of central positional deviation due to mechanical vibration at the rotation angle (θ coordinate) and the position on the R axis (R coordinate) at which the defect is detected are calculated from the measurement values (measurement data) of the displacement sensor and acceleration sensor, and the defect coordinates are corrected.

### <Summary>

(i) The defect inspection device (defect inspection system) 100 according to this embodiment includes an illumination and detection unit 20 having an illumination light source 22 for irradiating light (laser light) onto the sample 1 and a detection circuit (detector) 28 for detecting the inspection light from the sample 1, a stage device (stage mechanism) 10 that holds the sample 1 and has a linear stage 13 and a rotation stage 12, a displacement sensor (position sensor) 60 that measures the positions of the linear stage 13 and the rotation stage 12, and an acceleration sensor (accelerometer) 70 that measures the vibration of the linear stage 13 and the rotation stage 12, and a defect detection processing system (controller) 40 that determines defect coordinates that indicate the position of a defect on the sample 1 based on the measurement value by the displacement sensor 60. The defect detection processing system 40 then compares an output reference model (see FIG. 11B) of the acceleration sensor 70 calculated in advance according to the inspection mode (inspection conditions) that specifies the inspection method for the sample 1 with the value actually measured by the acceleration sensor 70 during inspection of the sample 1 according to the inspection mode to determine the amount of mechanical positional deviation in the stage device 10, and corrects the defect coordinates using the amount of mechanical positional deviation. The output reference model here is a characteristic that indicates the output value of the acceleration sensor 70 when there is no mechanical vibration of the linear stage 13 and the rotation stage 12 (see FIG. 11B). In this way, in the defect inspection device 100 that can select a mode among a plurality of inspection modes and perform inspection, it is possible to appropriately correct the deviation of the position of a detected defect (defect coordinates) in any inspection mode, thereby implementing defect inspection with high coordinate rule.

The inspection mode includes at least one of the following: a CAV inspection mode, which is an inspection method in which the rotation speed of the rotation stage is constant; a CLV inspection mode, which is an inspection method in which the scanning speed of light (illumination light) is constant; and an acceleration/deceleration inspection mode in which inspection is performed even during acceleration and deceleration of the linear stage 13. The inspection mode may be configured such that the operator can select it as appropriate, or may be configured to be set in advance. When an inspection mode is set, the defect detection processing system 40 corrects the defect coordinates based on the output reference model corresponding to the set inspection mode.

(ii) In this embodiment, the defect inspection system 100 performs positional deviation correction due to optical vibration in addition to positional deviation correction due to mechanical vibration. Specifically, the illumination and detection unit 20 includes a light beam position sensor (light position sensor) 50 that detects the optical displacement amount of light from the illumination light source 22 from the irradiation reference position. Then, the defect detection processing system 40 corrects the optical positional deviation amount included in the defect coordinates, based on the optical displacement amount detected by the light beam position sensor 50. No matter what illumination light source is used, deviations in the illumination position occur. In defect inspection in the related art, such irradiation positional deviation of illumination light does not have a significant effect on defect position detection. However, in a situation where defect sizes are becoming smaller as patterns formed on the sample (wafer) become finer, even slight positional deviation can make it difficult to identify the defect position. This embodiment therefore corrects positional deviation due to optical vibration (fluctuation of the illumination light) in addition to positional deviation due to mechanical vibration, making it possible to identify the defect position with high accuracy. The light beam position sensor 50 is installed on an extension of a part of the optical path from the illumination light source 22 to the sample 1. However, the installation position of the light beam position sensor 50 does not coincide with the light irradiation position on the sample 1. Therefore, a difference occurs between the deviation of the illumination light from the reference position (ideal optical axis) detected by the light beam position sensor 50 and the positional deviation on the sample 1. Therefore, the relationship between the optical displacement amount detected by the light beam position sensor 50 and the light irradiation positional deviation amount on the sample 1 is stored in advance in a storage device. The defect detection processing system 40 then obtains from the storage device the light irradiation positional deviation amount corresponding to the optical displacement amount actually detected by the light beam position sensor 50, and corrects the optical positional deviation amount by adding the light irradiation positional deviation amount to the defect coordinates. In this way, it is possible to accurately correct the positional deviation due to optical vibration.

(iii) As shown in FIG. 6, the defect inspection system 100 according to this embodiment is equipped with means for correcting the positional deviation due to optical vibration by signal processing, and means for correcting the positional deviation due to mechanical vibration by signal processing. Specifically, the defect detection processing system 40 corrects the positional deviation amount due to optical vibration of the illumination optical system and the positional deviation amount due to mechanical vibration of the stage mechanism at the defect coordinates, by using the optical displacement amount detected by the light beam position sensor 50 and the measurement values by the displacement sensor (position sensor) 60 and the acceleration sensor (accelerometer) 70. The positional deviation amount correction is a process different from the mechanism that prevents the occurrence of positional deviation by the anti-vibration mount 14 for reducing disturbance vibration from outside the defect inspection system 100 and disturbance vibration inside the defect inspection system 100. The positional deviation amount due to mechanical vibration in the stage device 10 in this embodiment includes a positional deviation amount due to vibrations that have a lower frequency than the disturbance vibrations and are not removed by the anti-vibration mount 14. The positional deviation correction according to this embodiment is not a mechanism that physically prevents the occurrence of positional deviation, as in the case of positional deviation removal by the anti-vibration mount 14 (the anti-vibration mount 14 structurally attenuates disturbance vibrations), but rather a process of detecting the optical positional deviation amount (vector value) and the mechanical positional deviation amount (vector value) as signals and correcting these positional deviation amounts by digital signal processing (adding the vector value corresponding to the positional deviation to the defect coordinates). In this way, positional deviation due to low-frequency vibrations can be efficiently corrected by signal processing, and highly accurate information on the defect position can be output.

In this embodiment, the defect detection processing system 40 also corrects the positional deviation amount due to high-frequency vibrations caused by the rotational operation of the rotation stage by signal processing, as the positional deviation amount due to mechanical vibrations. This makes it possible to accurately remove the effects of minute vibrations that cannot be removed by the anti-vibration mount 14.

(iv) The functions of this embodiment can also be implemented by software program code. In this case, a storage medium on which the program code is recorded is provided to the system or device, and the computer (or CPU or MPU) of the system or device reads the program code stored in the storage medium. In this case, the program code read from the storage medium itself implements the functions of the above-mentioned embodiments, and the program code itself and the storage medium on which the program code is stored configure the present disclosure. Examples of storage media for supplying such program code include flexible disks, CD-ROMs, DVD-ROMs, hard disks, optical disks, magneto-optical disks, CD-Rs, magnetic tapes, non-volatile memory cards, and ROMs.

Further, based on the instructions of the program code, an operating system (OS) running on a computer may perform some or all of the actual processing, and the functions of the above-mentioned embodiments may be implemented by this processing. Furthermore, after the program code is read from a storage medium and written into the memory on a computer, the CPU of the computer may perform some or all of the actual processing, and the functions of the above-mentioned embodiments may be implemented by this processing, based on the instructions of the program code.

Furthermore, the program code of the software that implements the functions of the embodiments may be distributed over a network and stored in a storage means such as a hard disk or memory of a system or device, or in a storage medium such as a CD-RW or CD-R, and the computer (or CPU or MPU) of the system or device may read and execute the program code stored in the storage means or storage medium when used.

The technology disclosed herein is not limited to the configuration example of this embodiment, but includes various modifications. This embodiment is provided to explain the technology disclosed herein in an easy-to-understand manner. Therefore, the technology disclosed herein is not necessarily limited to one that has all of the configurations described. Additionally, the processes and techniques described in the present embodiments are not inherently related to any particular apparatus and may be implemented by a combination of components. Furthermore, various types of general purpose devices may also be added. Specialized apparatus may be constructed to perform the functions of the present embodiments. Further, various functions may be formed by appropriately combining a plurality of components disclosed in the present embodiments. For example, some components may be deleted from all components shown in the embodiments, or different components may be combined as appropriate.

In this disclosure, specific embodiments are described, but these are in all respects for purposes of explanation (understanding the technology of the present disclosure) and not for purposes of limitation. It is considered that a person of ordinary skill in the art can understand that there are many combinations of hardware, software, and firmware suitable for implementing the technology of the present disclosure. For example, the software described can be implemented in a wide variety of programming or scripting languages, such as assembler, C/C++, perl, Shell, PHP, Java (registered trademark), etc.

Furthermore, in the above-described embodiment, the control lines and information lines are those considered necessary for the explanation, and not all control lines and information lines are necessarily shown in the product. All components may be interconnected.

In addition, other implementations of the present disclosure will become apparent from consideration of the present embodiment to a person skilled in the art. The specification and specific examples are merely representative, and the scope and spirit of the technology of the present disclosure are indicated by the following claims.

### REFERENCE SIGNS LIST

1: sample
10: stage device
11: sample stage
12: rotation stage
13: linear stage
14: anti-vibration mount
20: illumination and detection unit
21: illumination optical system
22: illumination light source
23: optical element
25: detection optical system
26: condensing optical element (condenser lens)
40: defect detection processing system
100: defect inspection device
N: rotation speed
O: center of sample
P1: sample transfer position
P2: scan start position
P3: sample periphery scanning position
G: gap between sample stage and illumination and detection unit

1. A defect inspection system that inspects a defect in a sample, comprising:
an illumination and detection unit having a light source that irradiates the sample with light and a detector that detects light from the sample;
a stage mechanism that holds the sample and has a linear stage and a rotation stage, a position sensor that measures positions of the linear stage and the rotation stage, and an accelerometer for measuring vibrations of the linear stage and the rotation stage; and
a control unit that determines defect coordinates indicating a position of the defect, based on measurement values by the position sensor, wherein
the control unit determines a mechanical positional deviation amount in the stage mechanism by comparing an output reference model of the accelerometer calculated in advance in accordance with an inspection mode that specifies an inspection method for the sample with a value actually measured by the accelerometer during inspection of the sample in accordance with the inspection mode, and corrects the defect coordinates using the mechanical positional deviation amount.

2. The defect inspection system according to claim 1, wherein
the output reference model represents an output value of the accelerometer when there is no mechanical vibration of the linear stage and the rotation stage.

3. The defect inspection system according to claim 1, wherein
the inspection mode includes at least one of a CAV inspection mode, which is an inspection method in which a rotation speed of the rotation stage is constant, a CLV inspection mode, which is an inspection method in which a scanning speed of the light is constant, or an acceleration/deceleration inspection mode in which inspection is performed even during acceleration and deceleration of the linear stage, and
the control unit corrects the defect coordinates based on the output reference model corresponding to an inspection mode selected by an operator or a preset inspection mode.

4. The defect inspection system according to claim 1, wherein
the illumination and detection unit includes a light position sensor that detects an optical displacement amount of light from the light source from an irradiation reference position, and
the control unit corrects an optical positional deviation amount contained in the defect coordinates, based on the optical displacement amount.

5. The defect inspection system according to claim 4, wherein
the control unit acquires an irradiation positional deviation amount of the light corresponding to the optical displacement amount actually detected by the light position sensor, from a storage device that stores a relationship between the optical displacement amount and the irradiation positional deviation amount of the light on the sample, and corrects the optical positional deviation amount by adding the irradiation positional deviation amount of the light to the defect coordinates.

6. A defect inspection system that inspects a defect in a sample, comprising:
an illumination and detection unit having a light source that irradiates a sample with light, a detector that detects light from the sample, and a light position sensor that detects an optical displacement amount from an irradiation reference position of light from the light source;
a stage mechanism that holds the sample and has a linear stage and a rotation stage, a position sensor that measures positions of the linear stage and the rotation stage, and an accelerometer for measuring vibrations of the linear stage and the rotation stage; and
a control unit that determines defect coordinates indicating a position of the defect, based on measurement values by the position sensor, wherein
the control unit corrects a positional deviation amount due to optical vibration of the illumination and detection unit and a positional deviation amount due to mechanical vibration of the stage mechanism at the defect coordinates, by using the optical displacement amount detected by the light position sensor and measurement values by the position sensor and the accelerometer.

7. The defect inspection system according to claim 6, wherein
the positional deviation amount due to the optical vibration and the positional deviation amount due to the mechanical vibration are vector values, and
the control unit corrects the positional deviation of the defect coordinates by reflecting the vector values to the defect coordinates.

8. The defect inspection system according to claim 6, wherein
the stage mechanism further has an anti-vibration mount for reducing disturbance vibration from outside the defect inspection system and disturbance vibration inside the defect inspection system, and
the positional deviation amount due to the mechanical vibration includes a first type of positional deviation amount due to vibration that has a lower frequency than the disturbance vibrations and is not removed by the anti-vibration mount.

9. The defect inspection system according to claim 8, wherein
the positional deviation amount due to the mechanical vibration further includes a second type of positional deviation amount due to vibration that has a higher frequency than the first type of positional deviation amount, the second type of positional deviation amount being due to the rotational operation of the rotation stage.

10. The defect inspection system according to claim 9, wherein
the anti-vibration mount structurally attenuates the disturbance vibration, and
the control unit performs as data processing, correcting the positional deviation of the defect coordinates, by adding the first type of positional deviation amount and the second type of positional deviation amount due to the mechanical vibration, as vector values, to values of the defect coordinates.
